(19) United States
(12) Patent Application Publication
(10) Pub. No.: US 2019/0213471 A1
(43) Pub. Date: Jul. 11, 2019

(54) NEUROMORPHIC COMPUTING DEVICE AND OPERATING METHOD THEREOF

(71) Applicant: ELECTRONICS AND TELECOMMUNICATIONS RESEARCH INSTITUTE, Daejeon (KR)

(72) Inventors: Young-deuk JEON, Sejong (KR); Min-Hyung CHO, Daejeon (KR)

(21) Appl. No.: 16/222,867

(22) Filed: Dec. 17, 2018

(30) Foreign Application Priority Data
Jan. 11, 2018 (KR) 10-2018-0004053

(51) Int. Cl. G06N 3/063

(52) U.S. Cl. CPC G06N 3/063; H03H 11/02

(57) ABSTRACT

Provided is a neuromorphic computing device including a differential signal generator configured to generate a plurality of first differential signals and a plurality of second differential signals on a basis of bits generated according to computation of each of a plurality of pieces of input data and each of a plurality of pieces of weight data corresponding thereto, a first capacitor synapse array configured to sample the plurality of pieces of first differential signals and output a first output voltage, a second capacitor synapse array configured to sample the plurality of pieces of second differential signals and output a second output voltage, a comparator configured to compare the first output voltage with the second output voltage to output a comparison result, and a successive approximation register (SAR) logic configured to control the first capacitor synapse array and the second capacitor synapse array on a basis of the comparison result and generate intermediate data.

### CROSS-REFERENCE TO RELATED APPLICATIONS

This U.S. non-provisional patent application claims priority under 35 U.S.C. § 119 of Korean Patent Application No. 10-2018-0004053, filed on Jan. 11, 2018, the entire contents of which are hereby incorporated by reference.

### BACKGROUND

The present disclosure herein relates to a neuromorphic computing device, and more particularly, to a neuromorphic computing device for performing convolution computation on the basis of a neural network and an operating method thereof.

A neuromorphic computing device is a device for simulating the nervous system or the brain of a human to process information. The neuromorphic computing device may be a computing device for simulating two-dimensional or three-dimensional connections of a plurality of neurons. Each neuron may be configured from circuits respectively corresponding to an axon, a dendrite, and a cell soma, which are similar to elements of a biological neuron, and a synapse for connecting between the neurons may be configured from a corresponding circuit.

Even though the neuromorphic computing device is implemented through a digital multiplier-accumulator (MAC), an analog MAC of low power and a small area is used for massive computation. The analog MAC uses a manner in which a plurality of digital input signals are converted into analog signals, and the converted analog signals are summed to be converted into a digital signal. In order to convert the digital signal to the analog signal, a memristor or a transistor-based current source may be used.

For the memristor, it is an issue of manufacturing the same in a separate process from a typical complementary metal-oxide semiconductor (CMOS) process. For the current source, the accuracy of a final digital output signal may be lowered due to mismatching of elements. In addition, when an analog-to-digital converter (ADC) is used in a process of converting a digital signal into an analog signal and converting the analog signal into a digital signal again, an error may occur in a computed result due to a gain error, an offset error or the like.

### SUMMARY

The present disclosure provides a neuromorphic computing device capable of removing error components in a computing process, and an operating method thereof.

An embodiment of the inventive concept provides a neuromorphic computing device including: a differential signal generator configured to generate a plurality of first differential signals and a plurality of second differential signals on a basis of bits generated according to computation of each of a plurality of pieces of input data and each of a plurality of pieces of weight data corresponding thereto; a first capacitor synapse array configured to sample the plurality of pieces of first differential signals and output a first output voltage; a second capacitor synapse array configured to sample the plurality of pieces of second differential signals and output a second output voltage; a comparator configured to compare the first output voltage with the second output voltage to output a comparison result; and a successive approximation register (SAR) logic configured to control the first capacitor synapse array and the second capacitor synapse array on a basis of the comparison result and generate intermediate data.

In an embodiment, the differential signal generator may include: a sign bit generation unit configured to generate a sign bit for a multiplication result of each of the plurality of pieces of input data and each of the plurality of pieces of weight data; a multiplication bit generation unit configured to multiply a first bit of each of the plurality of input data by a second bit of each of the plurality of weight data to generate a multiplication bit; and a digital differential signal generation unit configured to generate a first differential signal and a second differential signal on a basis of the sign bit and the multiplication bit.

In an embodiment, the sign bit generation unit may multiply a most significant bit of each of the plurality of pieces of input data and a most significant bit of each of the plurality of pieces of weight data to generate the sign bit.

In an embodiment, when the sign bit indicates a positive sign and the multiplication bit is 1, the digital differential signal generation unit may generate the first differential signal as 1 and the second differential signal as 0, when the multiplication bit is 0, the digital differential signal generation unit may generate each of the first differential signal and the second differential signal as 0, and when the sign bit indicates a negative sign and the multiplication bit is 1, the digital differential signal generation unit may generate the first differential signal as 0 and the second differential signal as 1.

In an embodiment, the first capacitor synapse array may include a plurality of first capacitors configured to correspond to the plurality of first differential signals, respectively, and the second capacitor synapse array may include a plurality of second capacitors configured to correspond to the plurality of second differential signals, respectively.

In an embodiment, the first capacitor synapse array may include a plurality of first switches configured to correspond to the plurality of first capacitors, respectively, and each of the plurality of first switches may connect one among a first differential signal, a power supply voltage or a ground voltage to a corresponding first capacitor, the second capacitor synapse array may include a plurality of second switches configured to correspond to the plurality of second capacitors, respectively, and each of the plurality of second switches may connect one among a second differential signal, the power supply voltage or the ground voltage to a corresponding second capacitor.

In an embodiment, a voltage corresponding to the first differential signal may be one of the power supply voltage or the ground voltage, and a voltage corresponding to the second differential signal may be one of the power supply voltage or the ground voltage.

In an embodiment, the SAR logic may control the plurality of first switches and the plurality of second switches according to a SAR scheme on the basis of the comparison result.

In an embodiment, when the first output voltage is equal to or smaller than the second output voltage, the comparator may output a first comparison result, and when the first output voltage is larger than the second output voltage, the comparator outputs a second comparison result, and when the first comparison result is output, the SAR logic may connect at least one among the plurality of first switches to the power supply voltage, and when the second comparison result is output, the SAR logic may connect at least one among the plurality of second switches to the power supply voltage.

In an embodiment, the SAR logic may sequentially determine the intermediate data from a most significant bit value to a least significant value on the basis of the comparison result.

In an embodiment, when a number of the plurality of pieces of input data is n, a number of bits of the intermediate data may be a bit number indicating values of a number smaller than 2n+1.

In an embodiment, the neuromorphic computing device may further include an adder configured to receive a plurality of pieces of intermediate data generated from the SAR logic, add the plurality of pieces of intermediate data on a basis of an order of magnitude of the plurality of pieces of intermediate data to calculate a convolution result of the plurality of pieces of input data and the plurality of pieces of weight data.

In an embodiment of the inventive concept, an operating method of a neuromorphic computing device is provided. The operating method includes: performing computation of each of a plurality of pieces of input data and each of a plurality of pieces of weight data corresponding thereto to generates bits; generating a plurality of first differential signals and a plurality of second differential signals on a basis of the generated bits; sampling the plurality of first differential signals to first capacitors and the plurality of second differential signals to second capacitors; comparing a first output voltage at a common node of the first capacitors and a second output voltage at a common node of the second capacitors to output a first comparison result; and connecting at least one of the first capacitors or at least one of the second capacitors to a power supply voltage on a basis of the first comparison result.

In an embodiment, the operating method may further include determining a first bit value of intermediate data on a basis of the first comparison result, wherein the intermediate data represents a sum of multiplication results of each bit of each of the plurality of pieces of input data by each bit of each of the plurality of pieces of weight data.

In an embodiment, the operating method may further include comparing the first output voltage with the second output voltage to output a second comparison result; and determining a second bit value of the intermediate data on a basis of the second comparison result.

In an embodiment, the operating method may further include connecting at least one among the first capacitors or at least one among the second capacitors to the power supply voltage on a basis of the second comparison result, when the second bit value is not a value of a least significant bit.

### BRIEF DESCRIPTION OF THE FIGURES

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 illustrates an example of a neural network according to an embodiment of the inventive concept;

FIG. 2 is a block diagram showing a neuromorphic computing device according to an embodiment of the inventive concept;

FIG. 3 shows examples of input data and weight data of FIG. 2;

FIG. 4 is a block diagram showing an example of a neuromorphic computing device of FIG. 2;

FIG. 5 shows an example of bits generated by a differential signal generator of FIG. 4;

FIG. 6 shows an example of intermediate data generated by an SAR logic;

FIG. 7 is a block diagram showing an example of a differential signal generator of FIG. 4;

FIG. 8 shows examples of a capacitor, a synapse array, a comparator, and an SAR logic of FIG. 4; and

FIG. 9 is a flowchart showing an operating method of the neuromorphic computing device according to an embodiment of the inventive concept.

### DETAILED DESCRIPTION

Hereinafter embodiments of the present inventive concept will be described in detail with reference to the accompanying drawings. In the following description, specific details such as detailed components and structures are provided to assist overall understanding of embodiments of the present disclosure. Therefore, various changes or modifications can be made by those of ordinary skill in the art in the specific details without departing from technical spirit and scope of the present disclosure. In addition, descriptions of well-known functions and constructions may be omitted for clarity and conciseness. Terms used herein are defined in consideration of functions of the present disclosure, and are not limited specific functions. The definitions of the terms can be determined based on details described in the specification.

Modules in the following drawing or description can be connected things other than elements shown in the drawing or described in the specification. Modules or elements can be respectively connected directly or indirectly to each other. Modules or elements can be respectively connected by communication or physical connection.

Elements described with reference to terms such as part, unit, module, or layer used in the description and functional blocks illustrated in the drawings can be implemented in a form of software, hardware, or a combination thereof. For example, the software can be machine code, firmware, embedded code, and application software. Also for example, the hardware can be electrical circuitry, electronic circuitry, processor, computer, integrated circuit, integrated circuit cores, a pressure sensor, an inertial sensor, a microelectromechanical system (MEMS), passive devices, or a combination thereof.

Unless defined otherwise, all the terms including technical or scientific terms used herein have the same meaning as those understood generally by a person having an ordinary skill in the art. The terms having the same meaning as those defined in generally used dictionaries shall be construed to have the meaning conforming to the contextual meaning of the related technologies, and shall not be construed as ideal or excessively formal meaning unless the terms are apparently defined in this application.

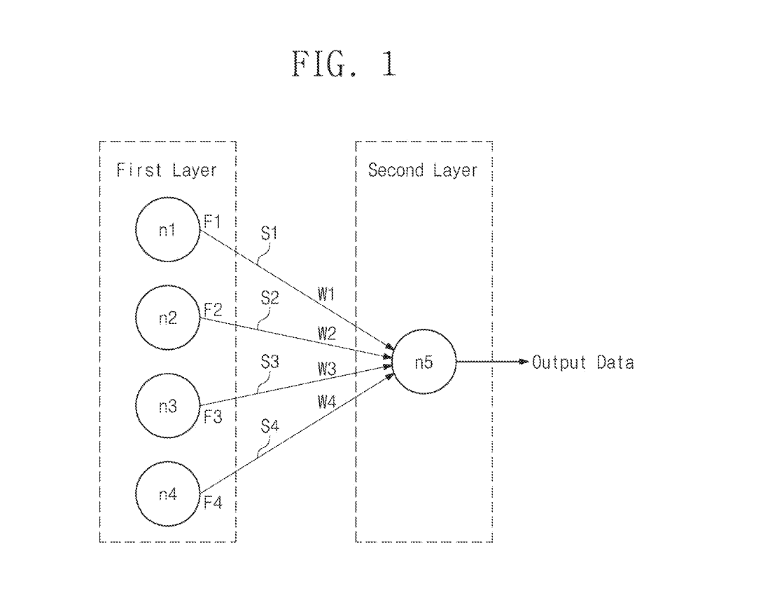

FIG. 1 illustrates an example of a neural network according to an embodiment of the inventive concept. Referring to FIG. 1, a first layer may include first to fourth neurons n1 to n4, and a second layer may include a fifth neuron n5. The first to fourth neurons n1 to n4 may be connected to the fifth neuron n5 through first to fourth synapses s1 to s4.

The synapse connecting between the neurons may include a weight. The weight may represent the connection intensity between the neurons. The first to fourth synapses s1 to s4 may respectively include first to fourth weight data W1 to W4. For example, the first weight data W1 may represent the connection intensity between the first neuron n1 to the fifth neuron n5. The first to fourth weight data W1 to W4 may be updated, when the connection intensities between the neurons change. The first to fourth neurons n1 to n4 may respectively deliver the first to fourth input data F1 to F4 to the fifth neuron n5 through the first to fourth synapses s1 to s4. The first to fourth input data F1 to F4 may data to be generated in the first to fourth neurons n1 to n4, respectively. For example, the first to fourth synapses n1 to n4 may respectively generate the first to fourth data F1 to F4 on the basis of image pixel values. For a convolution neural network (CNN), the first to fourth input data F1 to F4 may be feature data, and the first to fourth weight data W1 to W4 may be weight values of a mask (or a filter), a window, or a kernel.

The fifth neuron n5 may receive the first to fourth input data F1 to F4, and perform computation on the received first to fourth input data F1 to F4 and the first to fourth data W1 to W4. For example, the fifth neuron n5 multiplies the first to fourth input data F1 to F4 by the first to fourth weight data W1 to W4, respectively, and then adds the multiplied results. In other words, the fifth neuron n5 may perform convolution computation on the first to fourth input data F1 to F4 and the first to fourth weight data W1 to W4.

The fifth neuron n5 may generate output data on the basis of the computation result. For example, the fifth neuron n5 may generate, as the output data, the convolution computation result of the first to fourth input data F1 to F4 and the first to fourth weight data W1 to W4. Alternatively, the fifth neuron n5 may generate the output data on the basis of the convolution computation result and an activation function.

FIG. 1 illustratively shows the neural network in which the first to fourth neurons n1 to n4 are included in the first layer, and the fifth neuron n5 is included in the second layer. However the inventive concept is not limited thereto. The neural network according to an embodiment of the inventive concept may include various layers, and each layer may include various numbers of neurons.

As described above, the neuron of the neural network according to an embodiment of the inventive concept may perform the convolution computation. Hereinafter, for convenience of description, the inventive concept will be described on the basis of an example of a neuron that performs convolution computation on the first to fourth input data F1 to F4 and the first to fourth weight data W1 to W4 as shown in FIG. 1. However, the inventive concept is not limited thereto, and the inventive concept may be applied to a neuron that performs convolution computation of various numbers of input data and various numbers of weight data.

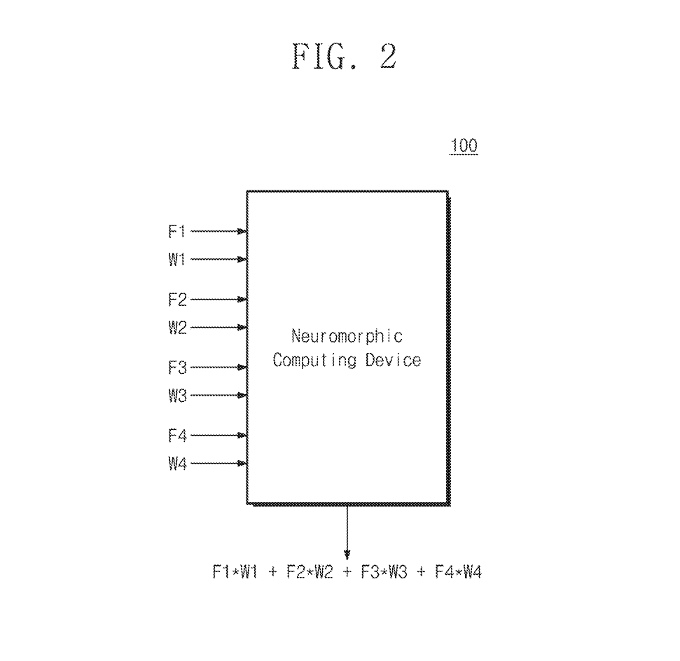

FIG. 2 is a block diagram showing a neuromorphic computing device according to an embodiment of the inventive concept. Referring to FIGS. 1 and 2, the neuromorphic computing device 100 may perform the convolution computation that is performed by the fifth neuron n5 of FIG. 1. The neuromorphic computing device may receive the first to fourth input data F1 to F4 and the first to fourth weight data W1 to W4. The neuromorphic computing device may perform the convolution computation on the first to fourth input data F1 to F4 and the first to fourth weight data W1 to W4. The neuromorphic computing device 100 may output a convolution computation result (F1*W1+F2*W2+F3*W3+F4*W4) through the convolution computation.

The first to fourth input data F1 to F4, the first weight data W1 to W4, and the convolution computation result (F1*W1+F2*W2+F3*W3+F4*W4) may be digital signals. In other words, the neuromorphic computing device 100 may receive the digital signals as an input, perform the convolution computation, and output the convolution computation result as a digital signal.

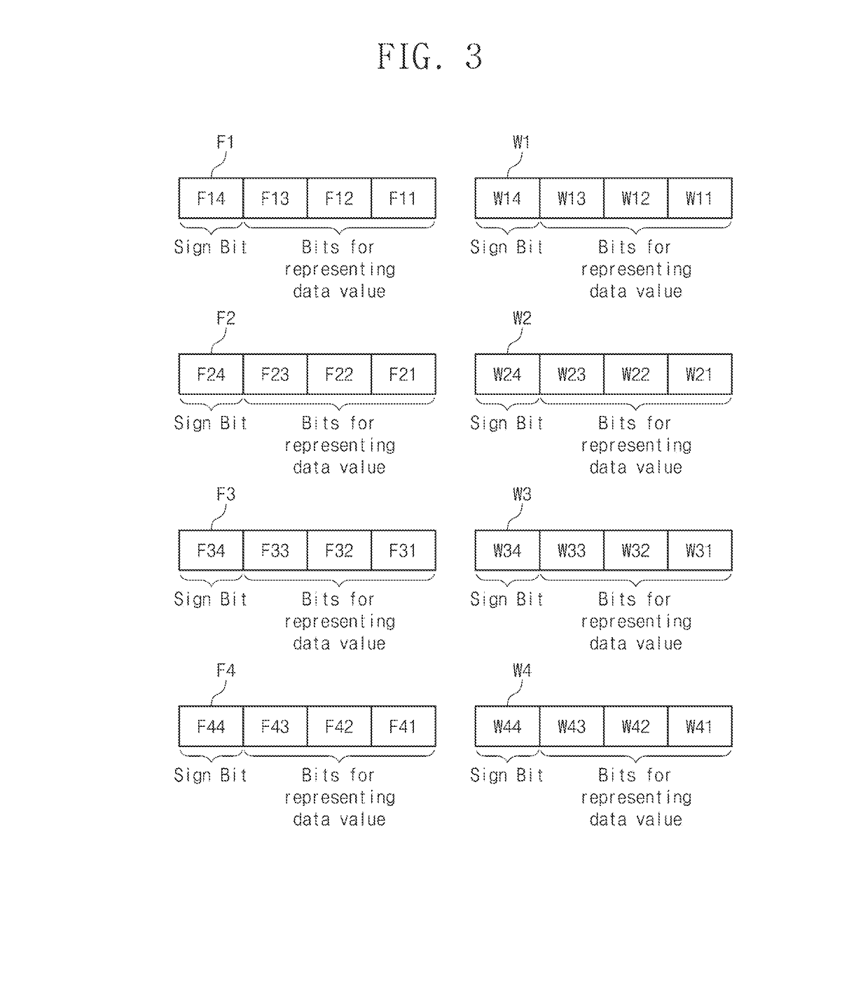

FIG. 3 shows examples of the input data and the weight data of FIG. 2. Referring to FIGS. 2 and 3, each piece of the first to fourth input data F1 to F4 and each piece of the first to fourth weight data W1 to W4 may have 4 bits. Hereinafter, for convenience of description, each of the input data and weight data will be described on the basis of the first data F1 and the first weight data W1.

The most significant bit (MSB) F14 of the first input data F1 may be a sign bit of the first input data F1, and the remaining less significant bits F13 to F1t may be bits for representing a data value of the first input data F1. The most significant bit (MSB) W14 of the first weight data W1 may be a sign bit, and the remaining less significant bits W13 to W11 may be bits for representing a data value of the first weight data W1. Each bit may be ‘0’ or ‘1’. For example, when the first input data F1 is ‘0011’, the first input data F1 may represent ‘(+)3’. When the first weight data W1 is ‘1101’, the first weight data W1 may represent ‘(−)5’.

As shown in FIG. 3, each of the first input data F1 and the first weight data W1 may be a digital signal of 4 bits, but the inventive concept is limited thereto. Each of the first to fourth input data F1 to F4 and the first to fourth weight data W1 to W4 may be a digital signal of various numbers of bits. Even though each of the first input data F1 and the first weight data W1 includes the most significant bit for representing a sign, the inventive concept is not limited thereto. In addition, each of the first to fourth input data F1 to F4 and the first to fourth weight data W1 to W4 may not include the sign bit.

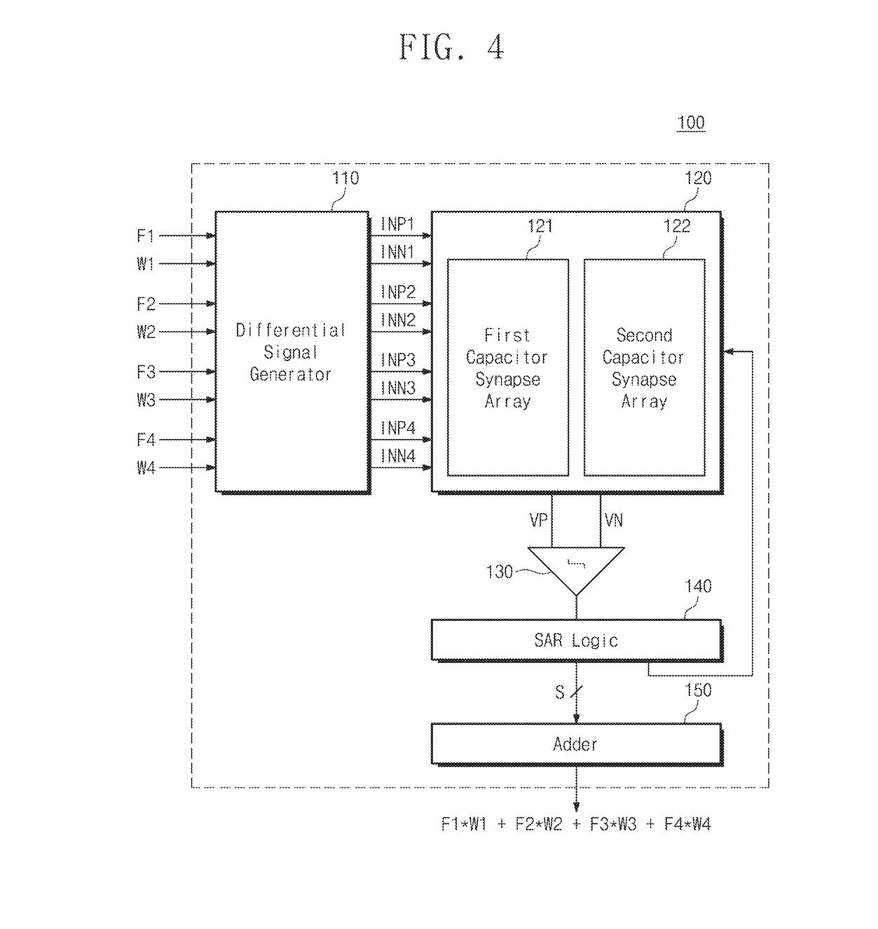

FIG. 4 is a block diagram showing an example of the neuromorphic computing device of FIG. 2. Referring to FIGS. 2 and 4, the neuromorphic computing device 100 may include a differential signal generator 110, a capacitor synapse array 120, a comparator 130, a successive-approximation register (SAR) logic 140 and an adder 150.

The differential signal generator 110 may receive the first to fourth input data F1 to F4 and the first to fourth weight data W1 to W4. For example, the differential signal generator 110 may perform computation on the first input data F1 and the first weight data W1 to generate bits. The differential signal generator 110 may generate a first differential signal INP1 and a second differential signal INNI on the basis of the generated bits. Similarly, the differential signal generator 110 may perform computation on the second to fourth input data F2 to F4 and the second to fourth weight data W2 to W4 to generate bits. The differential signal generator 110 may generate first differential signals INP2 to INP4 and second differential signals INN2 to INN4.

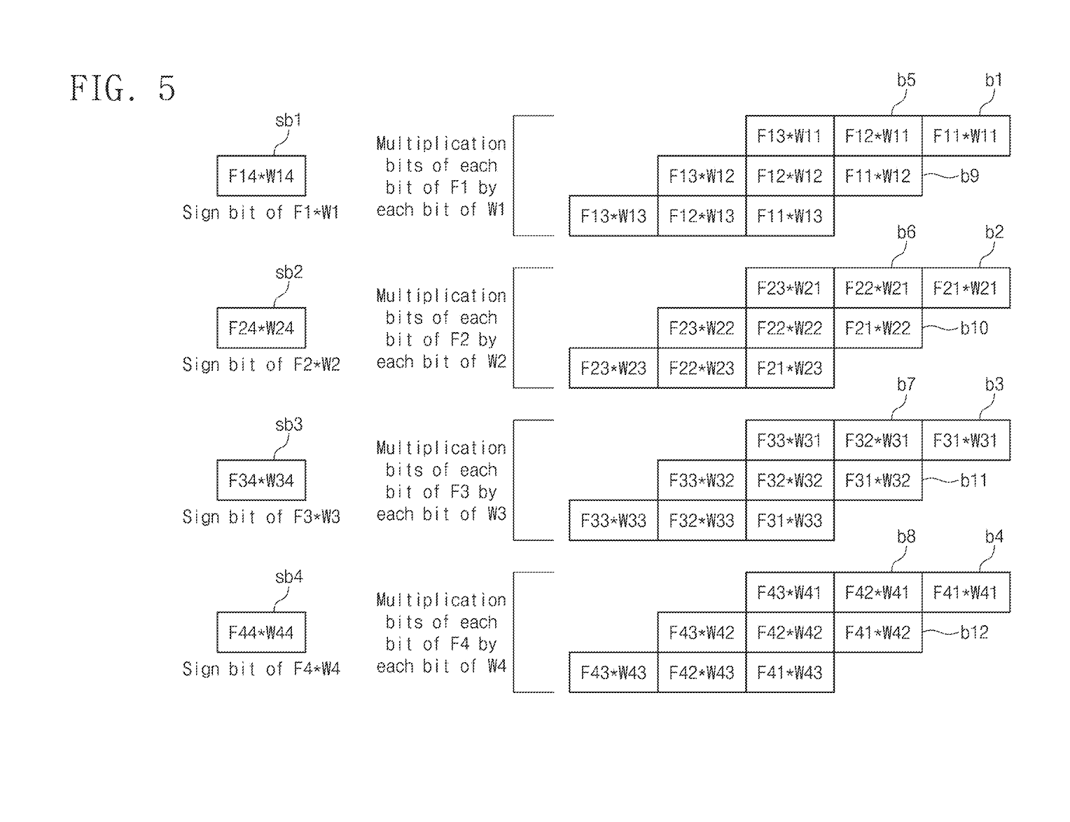

Hereinafter, an example will be described in which the differential signal generator 110 generates the first differential signals INP1 to INP4 and the second differential signals INN1 to INN4 with reference to FIG. 5. FIG. 5 shows an example of bits generated by the differential signal generator of FIG. 4.

The differential signal generator 110 may multiply the signal bit F14 of the first input data F1 by the signal bit W14 of the first weight data W1 to generate a first sign bit sb1 for the multiplication result of the first input data F1 and the first weight data W1. In addition, the differential signal generator 110 may multiply a first bit F11 of the first input data F1 by a second bit W11 of the first weight data W1 to generate a first multiplication bit b1. The differential signal generator 110 may generate the first differential signal INP1 and the second differential signal INNI on the basis of the generated first sign bit sb1 and multiplication bit b1.

As the manner in which the first sign bit sb1 is generated, the differential signal generator 110 may generate a second sign bit sb2 and multiply a first bit F21 of the second input data F2 by a second bit W21 of the second weight data W2 to generate the second multiplication bit b2. The differential signal generator 110 may generate the first differential signal INP2 and the second differential signal INN2 on the basis of the generated second sign bit sb2 and second multiplication bit b2.

Similarly, the differential signal generator 110 may generate the first differential signal INP3 and the first differential signal INN3 on the basis of a multiplication result of the third input data F3 and the third weight data W3. The differential signal generator 110 may generate the first differential signal INP4 and the second differential signal INN4 on the basis of a fourth signal bit sb4 and a fourth multiplication bit b4 for a multiplication result of the fourth input data F4 and the fourth weight data W4.

As described above, the differential signal generator 110 may generate the first differential signals INP1 to INP4 and the second differential signals INN1 to INN4 using multiplication bits having the same order of magnitude as a plurality of sign bits.

The differential signal generator 110 may generate the first differential signals INP1 to INP4 and the second differential signals INN1 to INN4 on the basis of the first to fourth sign bits sb1 to sb4 and the first to fourth multiplication bits b1 to b4, and then generate the first differential signals INP1 to INP4 and the second signals INN1 to INN4 on the basis of the first to fourth sign bits sb1 to sb4 and fifth to eighth multiplication bits b5 to b8. Then, the differential signal generator 110 may generate the first differential signals INP1 to INP4 and the second differential signals INN1 to INN4 on the basis of the first to fourth signal bits sb1 to sb4 and ninth to twelfth multiplication bits b9 to b12.

As shown in FIG. 3, when the number of bits for indicating a data value of the input data is 3 and the number of bits for indicating a data value of the weight data is 3, the differential signal generator 110 may generate 9 multiplication bits for the input data and the weight data. Accordingly, the first differential signals INP1 to INP4 and the second differential signals INN1 to INN4 generated from the differential signal generator 110 may have 9 types. This may be differed according to the number of bits of the input data and the number of bits of the weight data.

Referring to FIG. 4 again, the differential signal generator 110 may provide the generated first differential signals INP1 to INP4 and the second differential signals INN1 to INN4 to the capacitor synapse array 120.

The capacitor synapse array 120 may include a first capacitor synapse array 121 and a second capacitor synapse array 122. The first capacitor synapse array may sample the first differential signals INP1 to INP4. For example, the first capacitor synapse array 121 may sample the first differential signals INP1 to INP4 to a plurality of capacitors. The first capacitor synapse array 121 may output a first output voltage VP on the basis of the sampled signals.

The second capacitor synapse array 122 may sample the second differential signals INN1 to INN4. For example, the second capacitor synapse array 122 may sample the second differential signals INN1 to INN4 to a plurality of capacitors. The second capacitor synapse array 122 may output a second output voltage VN on the basis of the sampled signals. The capacitor synapse array 120 may provide the first output voltage VP and the second output voltage VN to the comparator 130.

The comparator 120 may compare the first output voltage VP with the second output voltage VN to generate a comparison result. For example, when the first output voltage VP is the second output voltage VN or smaller, the comparator 130 may generate a comparison result corresponding to a high value (namely, ‘1’). When the first output voltage VP is larger than the second output voltage VN, the comparator 130 may generate a comparison result corresponding to a low value (namely, ‘0’). The comparator 130 may provide the comparison result to the SAR logic 140.

The SAR logic 140 may generate intermediate data S on the basis of the comparison result received from the comparator 130. The intermediate data S may represent a sum of multiplication results of each bit of each piece of the first to fourth input data F1 to F4 by each bit of each piece of the first to fourth weight data W1 to W4. In this case, the sum of the multiplication results may a value obtained by considering the sign of the first to fourth input data F1 to F4 and the sign of the first to fourth weight data W1 to W4.

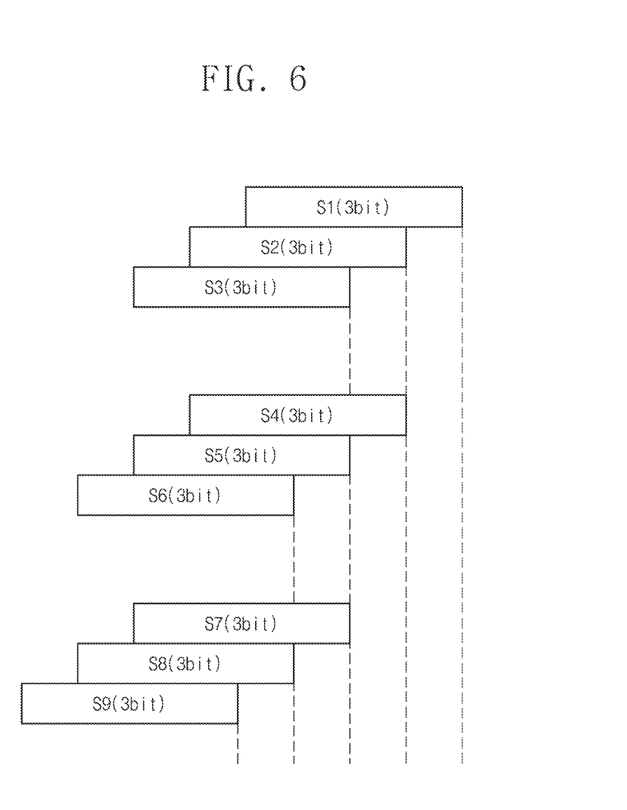

Hereinafter, an example of the intermediate data S generated by the SAR logic 140 will be described with reference to FIGS. 5 and 6. FIG. 6 shows an example of the intermediate data generated by the SAR logic.

When the first differentials signals INP1 to INP4 and the second differential signals INN1 to INN4 are generated on the basis of the first to fourth multiplication bits b1 to b4 of FIG. 5, the SAR logic 140 may generate first intermediate data S1 of FIG. 6. The first intermediate data S1 may represent a sum of the first to fourth multiplication bits b1 to b4 obtained by considering values of the first to fourth sign bits sb1 to sb4.

For example, when the value of the first sign bit sb1 of FIG. 5 is considered, the first multiplication bit b1 may represent one value among ‘−1’, ‘0’, and ‘1’. Similarly, when values of the second to fourth sign bits sb2 to sb4 are considered, each of the second to fourth bits b2 to b4 may represent one value among ‘−1’, ‘0’, and ‘1’. Since each multiplication bit may represent one value among ‘−1’, ‘0’, and ‘1’, the sum of the first to fourth multiplication bits b1 to b4 obtained by considering values of the first to fourth sign bits sb1 to sb4 may represent ‘−4’ to ‘4’.

As shown in FIG. 6, the first intermediate data S1 generated from the SAR logic 140 may have 3 bits. When the first intermediate data S1 has 3 bits, the intermediate data S1 may represent 8 values. As described above, the sum of the first to fourth multiplication bits b1 to b4 obtained by considering the first to fourth sign bits sb1 to sb4 may have 9 values. Accordingly, when the first intermediate data S1 is generated in 3 bits, the SAR logic 140 may represent two values using one value of the first intermediate data S1. For example, when the sum of the first to fourth multiplication bits b1 to b4 is ‘3’ or ‘4, the SAR logic 140 may generate the first intermediate data S1 as ‘111’.

When the number of input data input to the neurons in the neural network is n, the number of multiplication results for one bit of the input data and one bit of corresponding weight data may be n. Each multiplication result obtained by considering the sign may represent one of ‘−1’, ‘0’, and ‘1’, and the sum of each multiplication result may have (2n+1) values. In this case, the number of bits of the intermediate data S may represent values of the smaller number of bits than (2n+1).

As described above, when the number of bits of the intermediate data S is small, a computation result may be inaccurate, but the memory capacity and a computation speed may be improved. Deep learning using a neural network may perform massive computations and stochastically determine a computation result. Accordingly, even when accurate computation is not performed, a desired result may be derived therefrom and thus the neuromorphic computation device 100 may perform approximate computation by using the smaller number bits of intermediate data S. The neuromorphic computation device 100 may swiftly process the massive computation by performing the approximate computation.

However, the inventive concept is not limited thereto, and the neuromorphic computation device 100 may generate the intermediate data S having the number of bits that may represent (2n+1) values for accuracy of the computation. For example, the intermediate data S1 of FIG. 6 may be generated in 4 bits. When the number of bits is determined so as to represent the (2n+1) values, the computation accuracy may be improved. In other words, the number of bits of the intermediate data S may be determined in consideration of the computation accuracy and the computation speed.

When the first differential signals INP1 to INP4 and the second differential signals INN1 to INN4 are generated on the basis of the fifth to eighth multiplication bits b5 to b8 of FIG. 5, the SAR logic 140 may generate the second intermediate data S2 of FIG. 6. In addition, when the first differential signals INP1 to INP4 and the second differential signals INN1 to INN4 are generated on the basis of the ninth to twelfth multiplication bits b9 to b12 of FIG. 5, a fourth intermediate data S4 of FIG. 6 may be generated.

In this way, the SAR logic 140 may generate the first to ninth intermediate data S1 to S9. As shown in FIG. 5, since the number of multiplication bits of one bit of the input data and one bit of the weight data is 9, the SAR logic 140 may generate 9 intermediate data S.

Referring to FIG. 4 again, the SAR logic 140 may control the capacitor synapse array 120 on the basis of the comparison result. For example, the SAR logic 140 may control the capacitor synapse array 120 on the basis of an SAR scheme. The SAR logic 140 may determine bits of the intermediate data S from the MSB, and control the capacitor synapse array 120 in a binary search manner.

For example the SAR logic 140 may determine the MSB of the intermediate data S on the basis of a first comparison result, and transmit a control signal to the capacitor synapse array 120. The capacitor synapse array 120 may output the first output voltage VP and the second output voltage VN according to the control signal. The output first output voltage VP and second output voltage VN may be differed according to the control of the SAR logic 140. The comparator 130 may output a second comparison result of the first output voltage VP and the second output voltage VN. The SAR logic 140 may output a second bit of the intermediate data S on the basis of the second comparison result. The SAR logic 140 may transmit a control signal to the capacitor synapse array 120 again on the basis of the second comparison result. According to this process, the SAR logic 140 may determine the MSB to the least significant bit (LSB) of the intermediate data S. The SAR logic 140 may generate one piece of the intermediate data S by determining all bits of the intermediate data S.

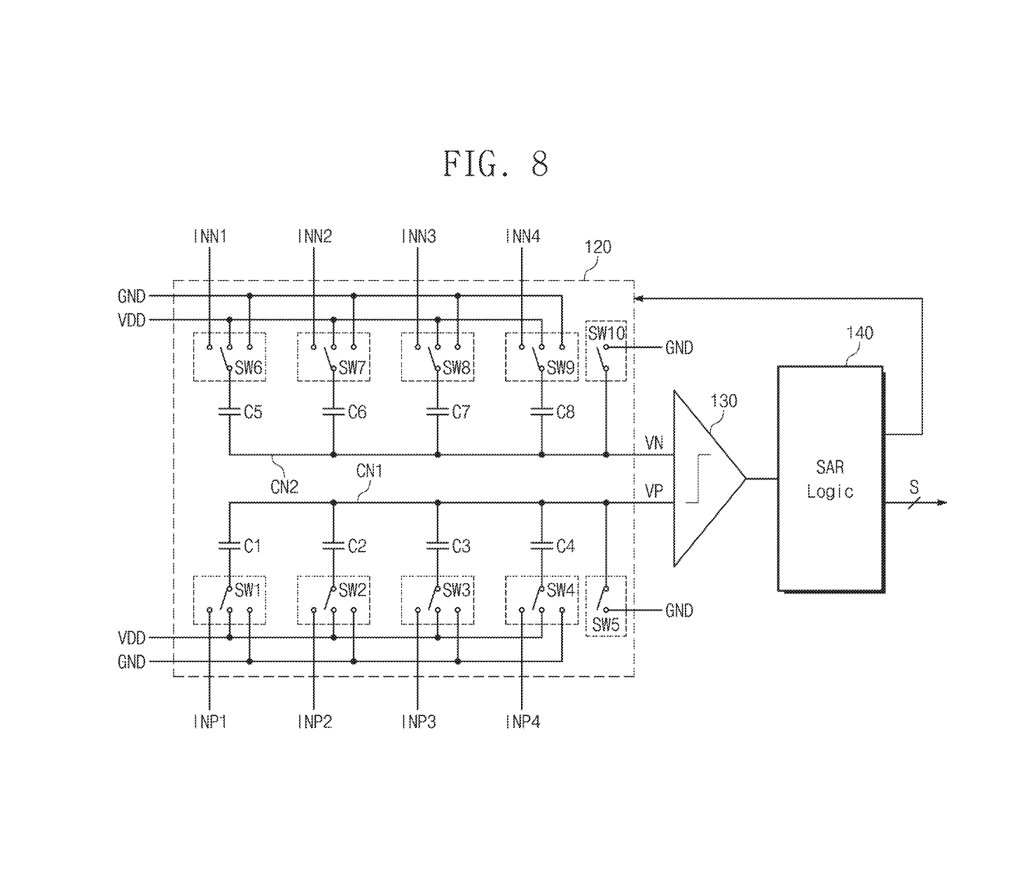

The control signal output from the SAR logic 130 may be determined in a binary search manner. With reference to FIG. 8, a detailed description will be provided about a control for the capacitor synapse array 120 on the basis of the SAR scheme by the SAR logic 140.

The SAR logic 140 may sequentially generate the intermediate data S on the basis of the input of the first differential signals INP1 to INP4 and the second differential signals INN1 to INN4. For example, as shown in FIG. 6, the SAR logic 140 may sequentially generate the first intermediate data S1 to the ninth intermediate data S9. The SAR logic 140 may provide the plurality of pieces of generated intermediate data S to the adder 150.

The adder 150 may receive the plurality of pieces of intermediate data S. The adder 250 may add the plurality of pieces of intermediate data S to output the convolution result of the first to fourth input data F1 to F4 and the first to fourth weight data W1 to W4. For example, the adder 150 may shift the intermediate data S on the basis of the order of magnitude of each of the plurality of pieces of intermediate data S. For example, the adder 150 may add the plurality of pieces of shifted intermediate data S to generate a convolution result.

For example, as shown in FIG. 6, the adder 150 adds the first to ninth intermediate data S1 to S9 to output a convolution result of the first to fourth input data F1 to F4 and the first to fourth weight data W1 to W4. The adder 150 may shift the first to ninth intermediate data S1 to S9 on the basis of the order of magnitude of each piece of the first to ninth intermediate data S1 to S9 and then perform addition according to the order of magnitude.

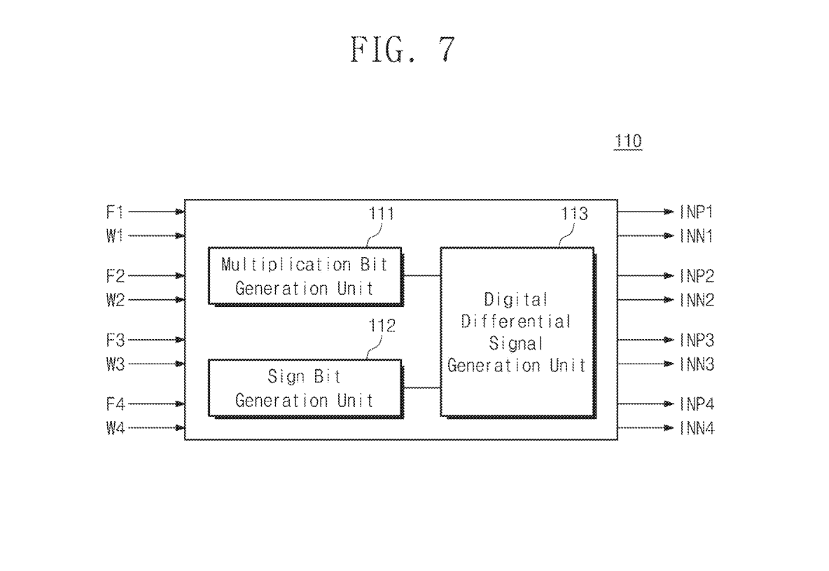

FIG. 7 is a block diagram showing an example of the differential signal generator of FIG. 4. Referring to FIGS. 4 and 7, the differential signal generator 110 may include a multiplication bit generation unit 111, a sign bit generation unit 112, and a digital differential signal generation unit 113.

The multiplication bit generation unit 111 may multiply one bit of each piece of the first to fourth input data F1 to F4 by one bit of each piece of the first to fourth weight data W1 to W4 to generate the multiplication bit. For example, as shown in FIG. 5, the multiplication bit generation unit 111 may multiply the first bit F1l of the first input data F1 by the second bit W11 of the first weight data W1 to generate the first multiplication bit b1.

The sign bit generation unit 112 may generate the sign bit for the multiplication result of each piece of the first to fourth input data F1 to F4 and each piece of the first to fourth weight data W1 to W4. For example, as shown in FIG. 5, the sign bit generation unit 112 may multiply the sign bit F14 of the first input data F1 and the sign bit W14 of the first weight data W1 to generate the first sign bit sb1 for the multiplication result of the first input data F1 and the first weight data W1.

The digital differential signal generation unit 113 may generate the first differential signals INP1 to INP4 and the second differential signals INN1 to INN4 on the basis of the multiplication bits generated from the multiplication bit generation unit 111 and the sign bits generated from the sign bit generation unit 112.

The following table 1 represents an example of the first differential signal INP and the second differential signal INN generated by the digital differential signal generation unit 113.

TABLE 1

| sign bit of F*W | 0(+) | 0(+) | 1(−) | 1(−) |
|---|---|---|---|---|
| one bit of F*one bit of W | 1 | 0 | 0 | 1 |
| INP | 1 | 0 | 0 | 0 |
| INN | 0 | 0 | 0 | 1 |

When the sign bit of the multiplication result of the input data F and the weight data W is ‘0’ (namely, ‘+’) and the multiplication result of one bit of the input data F and one bit of the weight data W is ‘1’, the first differential signal INP may be ‘1’. For example, when the first multiplication bit b1 of FIG. 5 is ‘1’, and the first sign bit sb1 is ‘0’, the first differential signal INP1 may be ‘1’.

When the sign bit of the multiplication result of the input data F and the weigh data W is ‘1’ (namely, ‘-’), and the multiplication result of one bit of the input data F and one bit of the weight data W is ‘1’, the second differential signal INN may be ‘1’. For example, when the first multiplication bit b1 of FIG. 5 is ‘1’ and the first sign bit sb1 is ‘1’, the second differential signal INN1 may be ‘1’.

Like Table 1, when the first differential signal INP is ‘1’, the second differential signal INN is ‘0’, and when the first differential signal INP is ‘0’, the second differential signal INN may be ‘1’. In addition, when the multiplication of one bit of the input data F and one bit of the weight data W is ‘0’, the first differential signal INP and the second differential signal INN may be all ‘0’.

In other words, the first differential signal INP and the second differential signal INN may be signals including magnitude and sign information on the multiplication of one bit of the input data F and on bit of the weight data W.

FIG. 8 shows examples of the capacitor, the synapse array, the comparator, and the SAR logic of FIG. 4. Referring to FIGS. 4 and 8, the capacitor synapse array 120 may include the first capacitor synapse array 121 and the second capacitor synapse array 122. The first capacitor synapse array 121 may include first and fourth capacitors C1 to C4 and first to fifth switches SW1 to SW5. The second capacitor synapse array 122 may include fifth to eighth capacitors C5 to C8 and sixth to tenth switches SW6 to SW10.

The capacitor synapse array 120 may receive the first differential signals INP1 to INP4 and the second differential signals INN1 to INN4. The first differential signals INP1 to INP4 may be input to one ends of the corresponding first to fourth capacitors C1 to C4. The second differential signals INN1 to INN4 may be input to one ends of the corresponding fifth to eighth capacitors C5 to C8.

When the first differential signals INP1 to INP4 and the second differential signals INN1 to INN4 are input, for sampling of each signal, the capacitor synapse array 120 may close the fifth switch SW5 and the tenth switch SW10. When the fifth switch SW5 and the tenth switch SW10 are closed, the ground voltage GND may be applied to a first common node CN1 of the first to fourth capacitors, and to a second common node CN2 of the fifth to eighth capacitors. Here, when the first to fourth switches SW1 to SW4 are connected to the first differential signals INP1 to INP4, the first to fourth capacitors C1 to C4 may be charged through the first differential signals INP1 to INP4. In addition, when the fifth to eighth switches SW5 to SW8 are connected to the second differential signals INN1 to INN4, the fifth to eighth capacitors C5 to C8 may be charged through the second differential signals INN1 to INN4.

For example, when the first differential signal INP1 is ‘1’, the first capacitor C1 may be charged with a voltage corresponding to ‘1’. When the second differential signal INN1 is ‘0’, the fifth capacitor C5 may be charged with a voltage corresponding to ‘0’. In this case, the voltage corresponding to ‘1’ may be a power supply voltage VDD and the voltage corresponding to ‘0’ may be the ground voltage GND.

After the charging is performed, the capacitor synapse array 120 may open the fifth switch SW5 and the tenth switch SW10. In this case, the first common node CN1 and the second common node CN2 may become a floating state. Then, when the first to fourth switches SW1 to Sw4 and the sixth to ninth switches SW6 to SW9 are connected to the ground voltage GND, the voltage at the first common node CN1 may be differed on the basis of the charged state of the first to fourth capacitors C1 to C4, and the voltage at the second common node CN2 may be differed on the basis of the charged state of the fifth to eighth capacitors C5 to C8. In other words, the first differential signals INP1 to INP4 may be sampled, and the second differential signals INN1 to INN4 may be sampled. In the specification, the voltage at the first common node CN1 may be referred to as the first output voltage VP, and the voltage at the second common node CN2 may be referred to as the second output voltage VN. The first output voltage VP and the second output voltage VN may be provided to the comparator 130.

For example, when the first differential signals INP1 to INP4 are respectively ‘1’, ‘1’, ‘0’, and ‘1’, and the second differential signals INN1 to INN4 are respectively ‘0’, ‘0’, ‘1’, and ‘0’, the first output voltage VP may be a voltage corresponding to −3′, and the second output voltage VN may be a voltage corresponding to ‘−1’.

The comparator 130 may compare the first output voltage VP with the second output voltage VN to output a comparison result. When the first output voltage VP is equal to or smaller than the second output voltage VN, the comparator 130 may output the comparison result corresponding to ‘1’, and when the first output voltage is larger than the second output voltage VN, the comparator 130 may output the comparison result corresponding to ‘0’. For example, when the first output voltage VP is the voltage corresponding to ‘−3’, and the second output voltage VN is the voltage corresponding to ‘−1’, the comparator 130 may output the comparison result corresponding to ‘1’, since the first output voltage is smaller than the second output voltage VN.

The SAR logic 140 may generate the intermediate data S on the basis of the comparison result. For example, the SAR logic 140 may generate the MSB of the intermediate data S on the basis of a first comparison result, and generate a second bit of the intermediate data S on the basis of a second comparison result. The MSB of the intermediate data S may represent the sign of the intermediate data S. When the MSB is ‘1’, the intermediate data S may represent a positive value, and when the MSB is ‘0’, the intermediate data S may represent a negative value. For example, the SAR logic 140 may generate the MSB of the intermediate data S as ‘1’ on the basis of the first comparison result corresponding to ‘1’.

The SAR logic 140 may control the capacitor synapse array 120 on the basis of the comparison result. The SAR logic 140 may control the capacitor synapse array 120 on the basis of the SAR scheme. The SAR logic 140 may control at least one among the first to fourth switches SW1 to SW4 or at least one among the sixth to ninth switches SW6 to SW9. For example, when the comparison result is ‘1’, the SAR logic 140 may control at least one among the first to fourth switches SW1 to SW4, and when the comparison result is ‘0’, the SAR logic 140 may control at least one among the sixth to ninth switches SW6 to SW9.

The SAR logic 140 may control the switches on the basis of the binary search manner. When the comparison results are sequentially input, the SAR logic 140 may reduce the number of control target switches by half. For example, the SAR logic 140 may control two among the first to fourth switches SW1 to SW4 or two among the sixth to ninth switches SW6 to SW9 on the basis of the first comparison result. The SAR logic 140 may control one among the first to fourth switches SW1 to SW4 or one among the sixth to ninth switches SW6 to SW9 on the basis of the second comparison result. When the switches are controlled on the basis of the second comparison result, the switches having been controlled on the basis of the first comparison result may be excluded from the control targets.

For example, the SAR logic 140 may connect the third and fourth switches SW3 and SW4 among the first to fourth switches SW1 to SW4 to the power supply voltage on the basis of the first comparison result corresponding to ‘1’. Then, the SAR logic 140 may connect the second switch SW2 among the first to fourth switches SW1 to SW4 to the power supply voltage VDD on the basis of the second comparison result corresponding to ‘1’.

As described above, the SAR logic 140 may reduce the number of control target switches by half on the basis of the binary search manner. As the SAR logic 140 controls the switches, the first output voltage VP and the second output voltage VN may be differed, and the comparison result of the comparator 130 may be differed. Accordingly, the SAR logic 140 may determine the bits of the intermediate data S, while sequentially controlling the switches according to the SAR scheme.

The following table 2 shows the intermediate data S generated by the SAR logic 140 and corresponding values, when the intermediate data S has 3 bits.

TABLE 2

| Intermediate value (3 bits) | Corresponding value |
|---|---|
| 000 | −4 |
| 001 | −3 |
| 010 | −2 |
| 011 | −1 |
| 100 | 0 |
| 101 | 1 |
| 110 | 2 |
| 111 | 3, 4 |

Hereinafter, an example will be described in which the intermediate data S representing ‘−2’ is generated.

For convenience of description, it is assumed that the first differential signals INP1 to INP4 input to the capacitor synapse array 120 are all ‘0’, and two among the second differential signals INN1 to INN4 are ‘1’. When sampling is performed on the first differential signals INP1 to INP4 and the second differential signals INNI to INN4, the first output voltage VP may be a voltage corresponding to ‘0’ and the second output voltage VN may be a voltage corresponding to ‘−2’. Since the first output voltage VP is larger than the second output voltage VN, the comparator 130 may output a first comparison result corresponding to ‘0’. The SAR logic 140 may determine the MSB of the intermediate data S as ‘0’ on the basis of the first comparison result. In addition, the SAR logic 140 may connect the two switches SW8 and SW9 among the sixth to ninth switches SW6 to SW9 to the power supply voltage VDD on the basis of the first comparison result. In this case, the second output voltage VN may be a voltage corresponding to ‘0’.

Accordingly, the first output voltage VP may be a voltage corresponding to ‘0’, and the second output voltage VN may be a voltage corresponding to ‘0’. Since the first output voltage VP is equal to or smaller than the second output voltage VN, the comparator 130 may output a second comparison result corresponding to ‘1’. The SAR logic 140 may determine the second bit of the intermediate data S as ‘1’ on the basis of the second comparison result. In addition, the SAR logic 140 may connect one switch SW2 among the first to fourth switches SW1 to SW4 to the power supply voltage VDD on the basis of the second comparison result. In this case, the first output voltage VP may be a voltage corresponding to ‘1’.

Accordingly, the first output voltage VP may be a voltage corresponding to ‘1’, and the second output voltage VN may be a voltage corresponding to ‘0’. Since the first output voltage VP is larger than the second output voltage VN, the comparator 130 may output a third comparison result corresponding to ‘0’. The SAR logic 140 may determine the LSB of the intermediate data S as ‘0’ on the basis of the third comparison result. In this case, since 3 bits of the intermediate data S are all determined, the SAR logic 140 may not control the switches any longer.

As described above, the intermediate data S representing ‘−2’ may be generated as ‘010’. Similarly, the intermediate representing ‘−4’ or ‘4’ may be generated as shown in Table 2.

As shown in Table 2, two pieces of the intermediate data S representing ‘3’ and ‘4’ may be identical as ‘111’. In this case, the accuracy of computation may be reduced, but the computation speed may be improved. Since the approximate computation may be performed in the neural network, it may be acceptable even when the computation accuracy is reduced a little.

Alternatively, the SAR logic 140 may include an overflow bit for improving the computation accuracy. When the intermediate data S is generated as ‘111’, the SAR logic 140 may determine whether a value represented by the intermediate data S is ‘3’ or ‘4’. When the value represented by the intermediate data is determined to be ‘4’, the SAR logic 140 may generate the overflow bit as ‘1’. The generated overflow bit may be delivered to the adder 150 and used for addition of the plurality of pieces of intermediate data S.

The SAR logic 140 may output the plurality of pieces of generated intermediate data S to the adder 150. For example, the SAR logic 140 may convert the plurality of pieces of generated intermediate data S into a 2's complement form, and deliver the converted intermediate data to the adder 150.

As described above, the neuromorphic computing device 100 may directly sample the first differential signals INP1 to INP4 and the second differential signals INN1 to INN4 that are digital signals, and convert the sampled values to digital values according to the SAR scheme. Accordingly, the neuromorphic computing device 100 may not include circuits such as a memristor, a current source and a sample-and-hold (S/H) amplifier necessary in a process of converting a digital signal to an analog signal and converting the analog signal to a digital signal again. Accordingly, the neuromorphic computing device 100 may implement in a low power and subminiature type, and minimize error factors occurable in various circuits.

Since the neuromorphic computing device 100 only uses the power supply voltage VDD corresponding to ‘1’ or the ground voltage GND corresponding to ‘0’ in the sampling process, a gain error may not be generated.

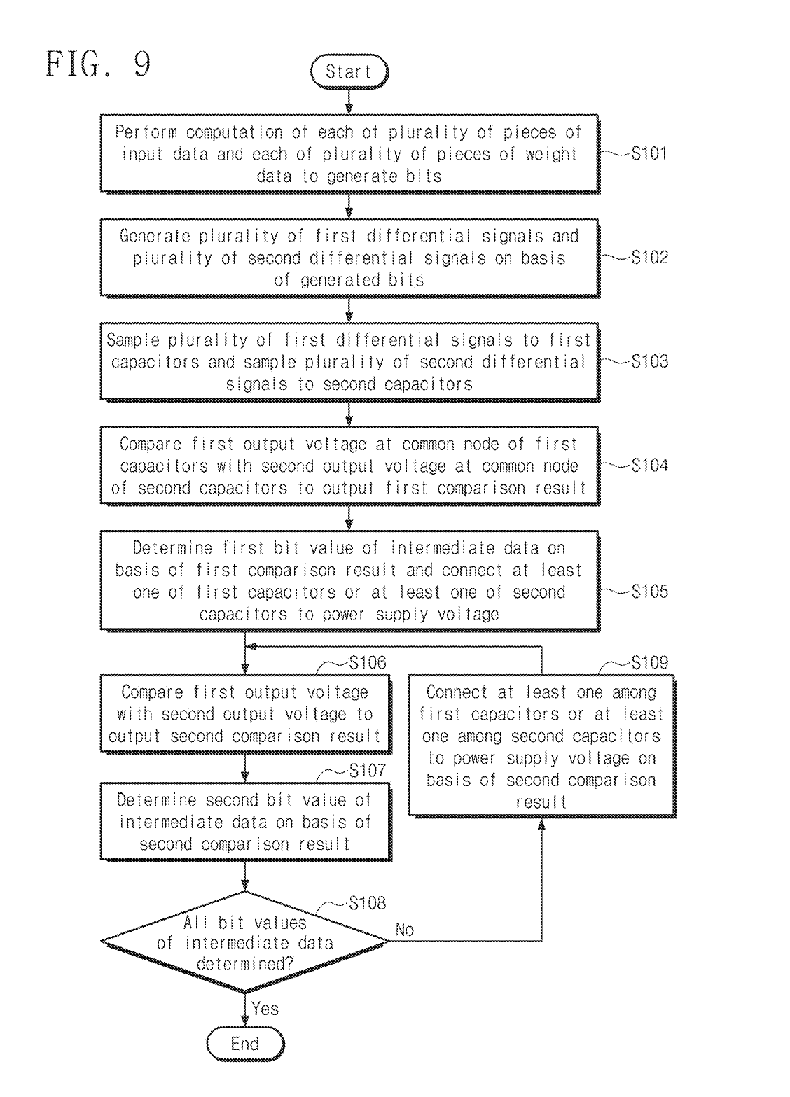

FIG. 9 is a flowchart showing an operating method of the neuromorphic computing device according to an embodiment of the inventive concept. Referring to FIG. 9, in operation S101, the neuromorphic computing device 100 may perform computation of each of a plurality of pieces of input data and each of a plurality of pieces of weight data to generate bits. For example, the neuromorphic computing device 100 may generate the sign bits sb1 to sb4 and the multiplication bits b1 to b4 in FIG. 5.

In operation S102, the neuromorphic computing device 100 may generate a plurality of first differential signals and a plurality of second differential signals on the basis of the generated bits. For example, the neuromorphic computing device 100 may generate the first differential signals INP1 to INP4 and the second differential signals INN1 to INN4 in FIG. 7.

In operation S103, the neuromorphic computing device 100 may sample the plurality of first differential signals to the first capacitors, and sample the plurality of second differential signals to the second capacitors. For example, as shown in FIG. 8, the neuromorphic computing device 100 may sample the first differential signals INP1 to INP4 to the first to fourth capacitors C1 to C4, and sample the plurality of second differential signals INN1 to INN4 to the fifth to eight capacitors C5 to C8.

In operation S104, the neuromorphic computing device 100 may compare the first output voltage at the common node of the first capacitors with the second output voltage at the common node of the second capacitors to output the first comparison result.

In operation S105, the neuromorphic computing device 100 may determine a first bit value of the intermediate data S on the basis of the first comparison result, and connect at least one of the first capacitors and at least one of the second capacitors to the power supply voltage VDD. For example, the neuromorphic computing device 100 may control the switches corresponding to the first capacitors or the second capacitors on the basis of the first comparison result. The neuromorphic computing device 100 may control the switches to connect at least one of the first capacitors or the second capacitors to the power supply voltage VDD.

In operation S106, the neuromorphic computing device 100 may compare the first output voltage with the second output voltage to output the second comparison result.

In operation S107, the neuromorphic computing device 100 may determine the second bit value of the intermediate data S on the basis of the second comparison result.

In operation S108, the neuromorphic computing device 100 may determine whether all bit values of the intermediate data S are determined. When all the bit values of the intermediate data S are determined, the neuromorphic computing device 100 may complete generation of the intermediate data S. When all the bit values of the intermediate data S are not determined, the neuromorphic computing device 100 may connect at least one among the first capacitors or at least one among the second capacitors on the basis of the second comparison result in operation S109.

Then, the neuromorphic computing device 100 may perform again operations S106 to S108. In this case, the second comparison result of operations S106 and S107 may be the third comparison result, and the third bit value of the intermediate data S may be determined. In other words, the neuromorphic computing device 100 may repeatedly perform operations S106 to S108 until the LSB value of the intermediate data S is determined.

A neuromorphic computing device according to embodiments of the inventive concept may be implemented in a low power and subminiature type, since there is not a process of converting a digital input signal into an analog signal.

In addition, the neuromorphic computing device according to the embodiments of the inventive concept may remove error components occurrable in an analog signal and accordingly, may increase accuracy of a final digital signal.

The above-described is detailed embodiments for practicing the present inventive concept. The present disclosure includes not only the above-described embodiments but also simply changed or easily modified embodiments. In addition, the present inventive concept also include techniques easily modified and practiced using the embodiments of the present disclosure. Therefore, the scope of the present disclosure is not limited to the described embodiments but is defined by the claims and their equivalents.

What is claimed is:

1. A neuromorphic computing device comprising:
a differential signal generator configured to generate a plurality of first differential signals and a plurality of second differential signals on a basis of bits generated according to computation of each of a plurality of pieces of input data and each of a plurality of pieces of weight data corresponding thereto;
a first capacitor synapse array configured to sample the plurality of pieces of first differential signals and output a first output voltage;
a second capacitor synapse array configured to sample the plurality of pieces of second differential signals and output a second output voltage;
a comparator configured to compare the first output voltage with the second output voltage to output a comparison result; and
a successive approximation register (SAR) logic configured to control the first capacitor synapse array and the second capacitor synapse array on a basis of the comparison result and generate intermediate data.

2. The neuromorphic computing device of claim 1, wherein the differential signal generator comprises:
a sign bit generation unit configured to generate a sign bit for a multiplication result of each of the plurality of pieces of input data and each of the plurality of pieces of weight data;
a multiplication bit generation unit configured to multiply a first bit of each of the plurality of input data by a second bit of each of the plurality of weight data to generate a multiplication bit; and
a digital differential signal generation unit configured to generate a first differential signal and a second differential signal on a basis of the sign bit and the multiplication bit.

3. The neuromorphic computing device of claim 2, wherein the sign bit generation unit multiplies a most significant bit of each of the plurality of pieces of input data and a most significant bit of each of the plurality of pieces of weight data to generate the sign bit.

4. The neuromorphic computing device of claim 2, wherein when the sign bit indicates a positive sign and the multiplication bit is 1, the digital differential signal generation unit generates the first differential signal as 1 and the second differential signal as 0,
when the multiplication bit is 0, the digital differential signal generation unit generates each of the first differential signal and the second differential signal as 0, and
when the sign bit indicates a negative sign and the multiplication bit is 1, the digital differential signal generation unit generates the first differential signal as 0 and the second differential signal as 1.

5. The neuromorphic computing device of claim 20, wherein the first capacitor synapse array comprises a plurality of first capacitors configured to correspond to the plurality of first differential signals, respectively, and
the second capacitor synapse array comprises a plurality of second capacitors configured to correspond to the plurality of second differential signals, respectively.

6. The neuromorphic computing device of claim 5, wherein the first capacitor synapse array comprises a plurality of first switches configured to correspond to the plurality of first capacitors, respectively,
each of the plurality of first switches connects one among a first differential signal, a power supply voltage or a ground voltage to a corresponding first capacitor,
the second capacitor synapse array comprises a plurality of second switches configured to correspond to the plurality of second capacitors, respectively, and
each of the plurality of second switches connects one among a second differential signal, the power supply voltage or the ground voltage to a corresponding second capacitor.

7. The neuromorphic computing device of claim 15, wherein a voltage corresponding to the first differential signal is one of the power supply voltage or the ground voltage, and a voltage corresponding to the second differential signal is one of the power supply voltage or the ground voltage.

8. The neuromorphic computing device of claim 20, wherein the SAR logic controls the plurality of first switches and the plurality of second switches according to a SAR scheme on the basis of the comparison result.

9. The neuromorphic computing device of claim 8, wherein when the first output voltage is equal to or smaller than the second output voltage, the comparator outputs a first comparison result, and when the first output voltage is larger than the second output voltage, the comparator outputs a second comparison result, and
when the first comparison result is output, the SAR logic connects at least one among the plurality of first switches to the power supply voltage, and when the second comparison result is output, the SAR logic connects at least one among the plurality of second switches to the power supply voltage.

10. The neuromorphic computing device of claim 10, wherein the SAR logic sequentially determines the intermediate data from a most significant bit value to a least significant value on the basis of the comparison result.

11. The neuromorphic computing device of claim 1, wherein when a number of the plurality of pieces of input data is n, a number of bits of the intermediate data is a bit number indicating values of a number smaller than 2n+1.

12. The neuromorphic computing device of claim 1, further comprising:
an adder configured to receive a plurality of pieces of intermediate data generated from the SAR logic, add the plurality of pieces of intermediate data on a basis of an order of magnitude of the plurality of pieces of intermediate data to calculate a convolution result of the plurality of pieces of input data and the plurality of pieces of weight data.

13. An operating method of a neuromorphic computing device, the operating method comprising:
performing computation of each of a plurality of pieces of input data and each of a plurality of pieces of weight data corresponding thereto to generates bits;
generating a plurality of first differential signals and a plurality of second differential signals on a basis of the generated bits;
sampling the plurality of first differential signals to first capacitors and the plurality of second differential signals to second capacitors;
comparing a first output voltage at a common node of the first capacitors and a second output voltage at a common node of the second capacitors to output a first comparison result; and
connecting at least one of the first capacitors or at least one of the second capacitors to a power supply voltage on a basis of the first comparison result.

14. The operating method of claim 13, further comprising:
determining a first bit value of intermediate data on a basis of the first comparison result,
wherein the intermediate data represents a sum of multiplication results of each bit of each of the plurality of pieces of input data by each bit of each of the plurality of pieces of weight data.

15. The operating method of claim 14, further comprising:
comparing the first output voltage with the second output voltage to output a second comparison result; and
determining a second bit value of the intermediate data on a basis of the second comparison result.

16. The operating method of claim 15, further comprising:
connecting at least one among the first capacitors or at least one among the second capacitors to the power supply voltage on a basis of the second comparison result, when the second bit value is not a value of a least significant bit.
